(19) United States
(12) Patent Application Publication
(10) Pub. No.: US 2024/0324110 A1
(43) Pub. Date: Sep. 26, 2024

(54) ELECTRONIC DISPLAY ASSEMBLY WITH FABRIC PANEL COMMUNICATIONS BOX

(71) Applicant: Manufacturing Resources International, Inc., Alpharetta, GA (US)

(72) Inventors: William Dunn, Alpharetta, GA (US); Mike Brown, Cumming, GA (US); Geoffrey Watson, Alpharetta, GA (US)

(21) Appl. No.: 18/736,994

(22) Filed: Jun. 7, 2024

Related U.S. Application Data
(63) Continuation of application No. 18/225,204, filed on Jul. 24, 2023, now Pat. No. 12,035,486.
(60) Provisional application No. 63/392,032, filed on Jul. 25, 2022.

(51) Int. Cl. H05K 5/00; G02F 1/1333; H05K 5/02; H05K 7/18; H05K 7/20

(52) U.S. Cl. CPC H05K 5/0004; G02F 1/133308; H05K 5/0204; H05K 5/0215; H05K 5/0243; H05K 5/0247; H05K 7/186; H05K 7/20172; H05K 7/20954; H05K 7/20972

(57) ABSTRACT

A display assembly, communications box, and related methods are disclosed. A display assembly includes an electronic display subassembly attached to a mounting structure. A communications box attached to the mounting structure has an interior space for electronic equipment which is located above, and spaced apart from, the electronic display subassembly. A gas permeable fabric panel of the communications box occupies at least a majority of a side of the communications box and is gas permeable, such as to allow airflow to electronics contained therein.

### CROSS-REFERENCE TO RELATED APPLICATIONS

This application is a continuation of U.S. patent application Ser. No. 18/225,204 filed Jul. 24, 2023, which claims the benefit of U.S. provisional patent application Ser. No. 63/392,032 filed Jul. 25, 2022, the disclosures of which are hereby incorporated by reference as if fully restated herein.

### TECHNICAL FIELD

Exemplary embodiments relate generally to electronic display assemblies with fabric panel communications boxes, and systems and methods related to the same.

### BACKGROUND AND SUMMARY OF THE INVENTION

It has become increasingly desirable to include certain electronic equipment with display assemblies featuring electronic displays. Such electronic equipment may include, for example, communications equipment, sensing equipment, combinations thereof, and the like. For example, advertising or announcements may be displayed at the electronic displays and internet connectivity may be facilitated by the electronic equipment. Such electronic displays and electronic equipment may be provided in ruggedized housings to protect the electronic displays and equipment from harsh environmental conditions. Sometimes, at least some of the electronic equipment is provided in a box above the electronic displays. An example of such an assembly includes US Pub. No. 2022/0110227 published Apr. 7, 2022 (the “227 Publication”). The elevated position of the box may facilitate signal propagation and reception. The electronic equipment located in the box may generate heat and have cooling requirements. However, certain types of signals may be difficult to transmit or receive through certain materials.

What is needed is an electronic display assembly with a communications box which facilitates thermal management as well as signal transmission and reception. An electronic display assembly with a communications box having one or more fabric panels is disclosed. The fabric panels may facilitate thermal management, such as cooling, and/or signal transmission and/or reception.

Advancements in network communications, particularly in wireless communications technology, have brought about equipment with greater power consumption. These higher power level operations may increase heat production, which likewise increases cooling needs. These advancements may, alternatively or additionally, utilize signal types which are attenuated by certain materials. One such example, without limitation, is “5G” wireless technology, which may, for example, consume on the order of 500-700 watts during normal operations and whose signals may see significant attenuation through materials such as metals and glass.

The fabric panel(s) of the communications box may be snap fitted to one or more frames, by way of non-limiting example. This may permit the panels to be periodically changed, for example. The fabric panels may comprise patterned apertures which may permit ingestion and/or exhaustion of ambient air, such as by way of passive airflow. Alternatively, or additionally, an intake/exhaust area may be provided along an upper edge of the communications box with or without fans, such as for active cooling of the communications box. Alternatively, or additionally, fans may be located within the communications box, such as for forcing ingestion and/or exhaustion of ambient air through the fabric panels. The communications box may be fluidly separated from, or connected to, side assemblies. The side assemblies may be located below the communications box and comprise electronic displays. The assembly may comprise other airflow pathways. Wireless networking equipment and/or other electronic equipment may be housed within the communications box to receive airflow, such as for cooling. Other electronic equipment may be located within the assembly, such as for operating the side assemblies or providing other features.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical or equivalent features, and wherein:

FIG. 1 is a perspective view of an exemplary display assembly;

FIG. 2 is a perspective view of another exemplary display assembly with certain cladding components removed to reveal internal components, also indicating Detail A;

FIG. 3 is a detailed perspective view of a communications box of Detail A of the display assembly of FIG. 2, also indicating section line A-A;

FIG. 4 is a side sectional view of the communications box taken along section line A-A of FIG. 3;

FIG. 5 is a perspective view of the communications box of FIG. 3 with certain fabric paneling removed to reveal internal components, also indicating section line B-B;

FIG. 6A is a perspective sectional view of an exemplary embodiment of the communications box taken along section line B-B of FIG. 5;

FIG. 6B is a perspective sectional view of another exemplary embodiment of the communications box taken along section line B-B of FIG. 5;

FIG. 7 is a side sectional view of another exemplary embodiment of the communications box taken along section line A-A of FIG. 3;

FIG. 8 is a side sectional view of another exemplary embodiment of the communications box taken along section line A-A of FIG. 3;

FIG. 9 is a detailed perspective view of another exemplary embodiment of the communications box; and

FIG. 10 is a detailed perspective view of another exemplary embodiment of the communications box.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

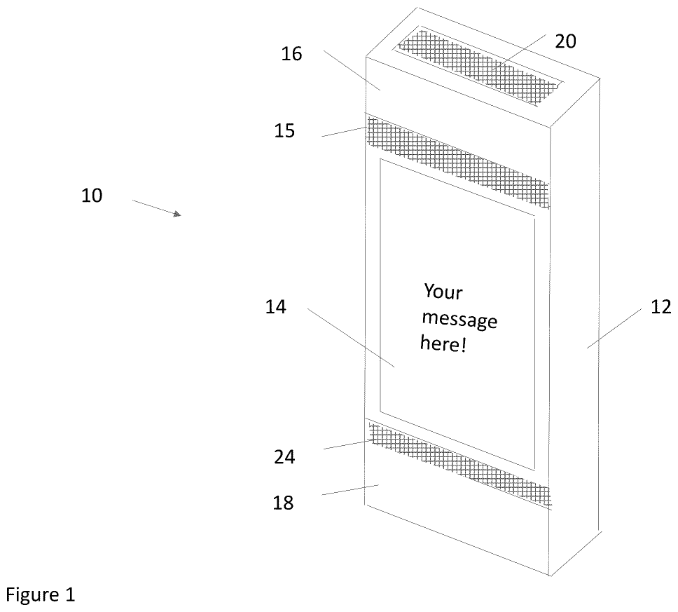

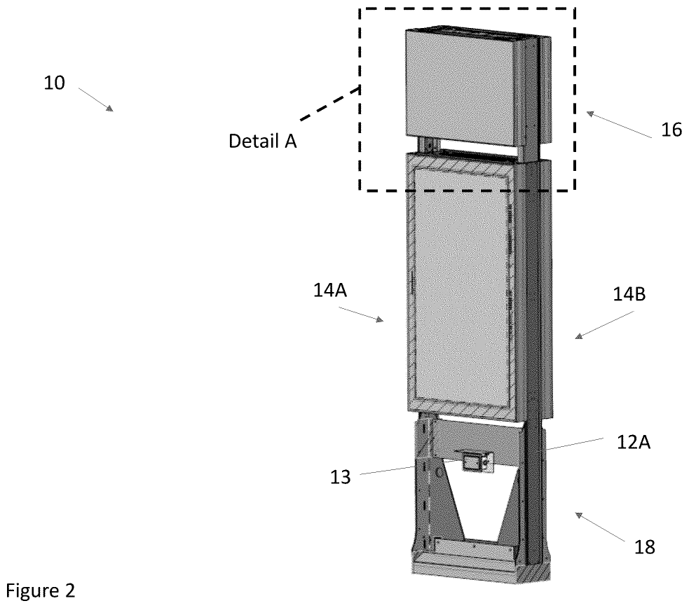

Referring particularly to FIG. 1 and FIG. 2, an exemplary display assembly 10 is illustrated. The display assembly 10 may comprise a mounting structure 12. The mounting structure 12 may comprise one or more members arranged into a framework. The mounting structure 12 may comprise one or more external cladding components, such as panels. The mounting structure 12 may serve as a chassis and/or housing for components of the display assembly 10. The mounting structure 12 may be configured to facilitate mounting the assembly 10 to a surface, such as but not limited to, a sidewalk, parking lot, ground, wall, building, combinations thereof, or the like.

The display assembly 10 may comprise one or more electronic display subassemblies 14. For example, without limitation, a first and second electronic display subassembly 14A, 14B may be positioned in a back-to-back arrangement at the mounting structure 12, though any number and location of such electronic display subassemblies 14 may be utilized. The electronic display subassemblies 14 may be moveably mounted to said mounting structure 12, such as, but not limited to, in a hinging fashion. Alternatively, or additionally, the display assembly 10 may comprise one or more static poster subassemblies, which may be configured to house one or more static posters in an illuminated or non-illuminated fashion and/or one or more black covers such as in place of one or more of the electronic display subassemblies 14.

The display assembly 10 may comprise a communications box 16. In exemplary embodiments, without limitation, the communications box 16 may be located above, and spaced apart from, and upper edge of the one or more electronic display assemblies 14, though such is not required.

The display assembly 10 may comprise a lower compartment 18. The lower compartment 18 may be located below the one or more electronic display assemblies 14. The lower compartment 18, in exemplary embodiments without limitation, may be at least partially defined by at least a first portion of the mounting structure 12A. The lower compartment 18 may be configured to house one or more electronic equipment items 13. Such electronic equipment items 13 may comprise, for example, without limitation, processors, electronic storage devices, power modules, power transformers, bulk energy storage devices, video players, wiring (e.g., power, network connectivity), network connectivity devices, combinations thereof, or the like. The lower compartment 18 may, alternatively or additionally, serve to elevate the one or more electronic display assemblies 14 to an ergonomically viewable height.

The communication box 16, in exemplary embodiments without limitation, may be at least partially defined by at least a second portion of the mounting structure 12B. The second portion of the mounting structure 12B may comprise one or more framework members which elevate the communication box 16 above the one or more electronic display assemblies 14 such that it is spaced apart from the one or more electronic display assemblies 14. Some or all of the second portion of the mounting structure 12B and/or communication box 16 may comprise fiberglass, polymer, or the like, which may permit improved signal transmission and/or reception over metal, by way of non-limiting example. Coverings, grills, cladding, combinations thereof, or the like, may extend between the one or more electronic display assemblies 14 and the communications box 16, though such is not required.

Each of the one or more electronic display assemblies 14 may comprise, for example, without limitation, one or more of: an electronic display layer, a backlight, one or more airflow pathways (e.g., open loop, closed loop, for ambient air, for circulating gas, combinations thereof, or the like), electronic components (e.g., processors, electronic storage devices, timing and control boards, video players, combinations thereof, or the like), one or more optical films, diffusion layers, fans, combinations thereof, or the like. The electronic display subassemblies 14 may comprise of any type of electronic display including, but not limited to, LCD displays, LED displays, plasma displays, OLED displays, or the like. Such electronic displays may be directly backlit, edge lit, combinations thereof, or the like.

The display assembly 10 may comprise one or more intake areas 15. The one or more intake areas 15 may be located on, at, along, or above an upper edge of the one or more electronic display assembles 14. The one or more intake areas 15 may comprise one or more apertures, grills, holes, filters, combinations thereof, or the like configured to facilitate the ingestion of ambient air, such as for thermally managing the electronic display assemblies 14. In exemplary embodiments, without limitation, a single intake area 15 is common to all of the one or more electronic display assembles 14, though separate intake areas 15 may be utilized.

The display assembly 10 may comprise one or more exhaust areas 24. The one or more exhaust areas 24 may be located on, at, along, or below the one or more electronic display assemblies 14. The one or more exhaust areas 24 may comprise one or more apertures, grills, holes, filters, combinations thereof, or the like configured to facilitate the exhaustion of the ingested ambient air from the assembly 10, such as after used to extract heat from the electronic display assemblies 14. The one or more exhaust areas 24 may be fluidly connected to the one or more intake areas 15. In exemplary embodiments, without limitation, separate exhaust areas 24 may be used for each of the one or more electronic display assembles 14, though common exhaust area(s) 26 may be utilized.

The communications box 16 may be spaced apart from the one or more display assemblies 14 to facilitate ingestion of ambient air into the one or more intake areas 15 for the one or more display assemblies 14 and/or other portions of the assembly 10 not forming part of the communications box 16 in exemplary embodiments, without limitation. This may provide partial or entire fluid separation between ambient air ingested into the one or more electronic display assemblies 14 and any ambient air ingested into the communications box 16. This may advantageously limit or prevent pre-heating of ambient air ingested into the one or more electronic display assemblies 14, which, for example, might otherwise be provided where passed through the communications box 16 first.

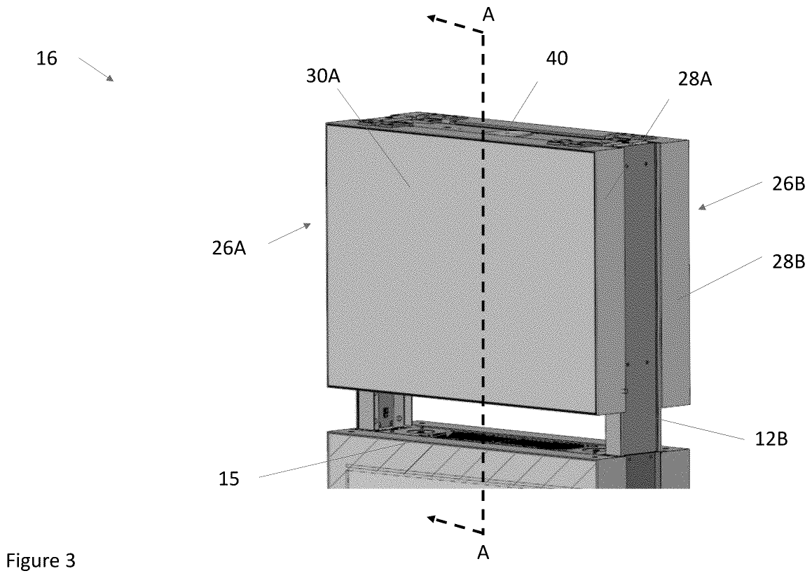

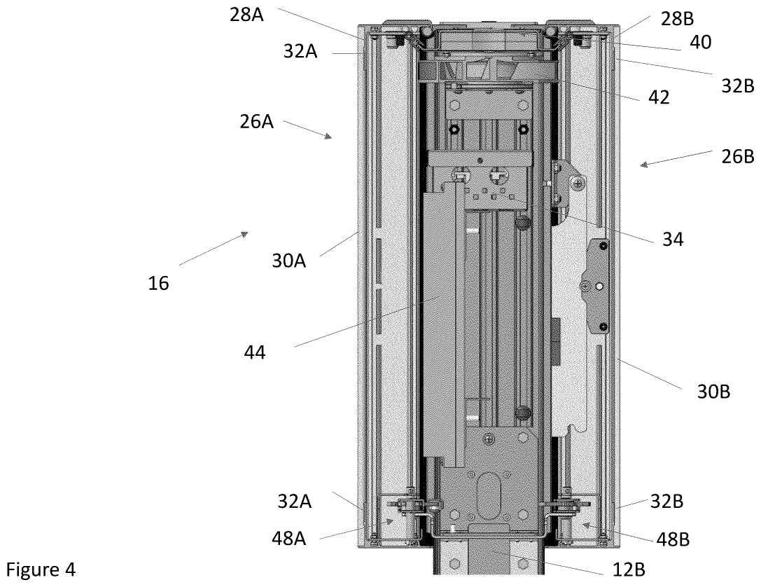

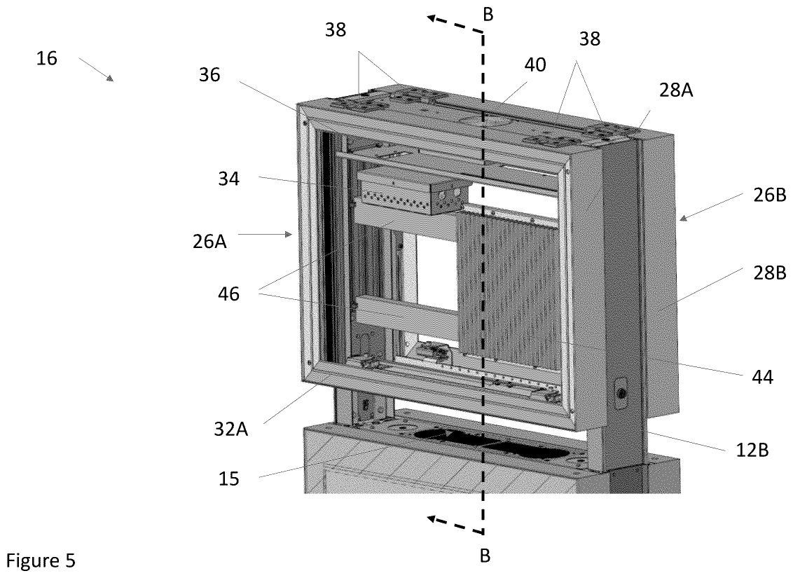

Referring particularly to FIG. 3 through FIG. 5, the communications box 16 may comprise a second portion of the mounting structure 12B. The second portion of the mounting structure 12B may comprise one or more members forming a framework, one or more cladding components, combinations thereof, or the like. Some or all components of the first and second portions of the mounting structure 12A, 12B may be common to one another or separate. The communications box 16 may comprise one or more panel frames 28. The one or more panel frames 28 may be connected to the second portion of the mounting structure 12B. The one or more panel frames 28 may be connected to the second portion of the mounting structure 12B in a moveable manner, such as by way of one or more hinging devices 38. In exemplary embodiments, without limitation, a first one of the panel frames 28A is connected to a first side of the mounting structure 12 and a second one of the panel frames 28B is connected to a second, opposing side of the mounting structure 12, though any number of panel frames 28 may be provided in any arrangement.

Each of the panel frames 28 may be configured to accept one or more fabric panels 30. In exemplary embodiments, without limitation, each of the panel frames 28 is configured to accept one of the fabric panels 30. Each of the panel frames 28, for example, without limitation, may comprise one or more securing structures 32. The securing structures 32 may comprise, for example, without limitation, one or more ridges, protrusions, clamps, apertures, pins, combinations thereof, or the like configured to removably receive and secure the fabric panels 30, such as, but not limited to, in a snap-fit, friction fit, fastened, and/or clamping arrangement, combinations thereof, or the like. The fabric panels 30 may be periodically removed and replaced, such as to facilitate changing of advertising images or announcements, replace dirty panels 30, to name a few non-limiting examples. The fabric panels 30 may alternatively be removed, cleaned, and re-installed. The fabric panels 30 may, alternatively or additionally, comprise one or more securing structures, such as, but not limited to, ridges, protrusions, clamps, apertures, pins, combinations thereof, or the like configured to interact with the securing structures 32 of the panel frames 28.

In exemplary embodiments, without limitation, each of the panel frames 28A, 28B may comprise a respective securing structure 32A, 32B, such as, but not limited to, in the form of a ridge which extends a perimeter or the panel frame 28 to receive one of the fabric panels 30 in a snap-fit type arrangement. Alternatively, or additionally, the securing structures 32 may comprise holes configured to receive shock cords, cable ties, rope, string, wire, combinations thereof, or the like, passed through the fabric panels 30, such as by way of corresponding apertures located in the same.

In exemplary embodiments, without limitation, each of the communications boxes 16 may comprise first and second frames 28A, 28B provided on opposing sides of the communications box 16 with a first and second panel 30A, 30B, respectively. However, the communications box 16 may comprise any number, arrangement, and/or type of frames 28 and/or panels 30. For example, without limitation, one side of the communications box 16 may comprise a frame 28A and fabric panel 30A while another comprises a metal and/or glass panel (with or without a frame 28B). Some or all of the frames 28, by way of example, may comprise fiberglass, polymer, or the like, which may permit improved signal transmission and/or reception over metal, by way of non-limiting example.

The fabric panels 30 may comprise, for example without limitation, a number of apertures. The apertures may be spaced and/or arranged randomly and/or in any pattern, such as, but not limited to, in a mesh, scrim, combinations thereof, or the like. The fabric panels 30 may comprise vinyl, polyester, combinations thereof, or the like. In exemplary embodiments, without limitation, the materials to apertures may be provided in a 70/30 and/or 80/20 ratio, though any ratio may be utilized. The fabric panels 30 may be configured to receive one or more printed images, such as for advertising or other announcements. Examples of suitable fabric panels 30, without limitation, include those available from Signs.com of Salt Lake City, UT (www.signs.com/mesh-banners/), Duratex of St. Louis, MO (www.duratexmedia.com/8 oz-mesh-banner-with-liner.html), and/or Fellers Inc. of Tulsa OK (www.fellers.com/fellers-shopping/cat/banner-material/sub/mesh-perforated-banner/set/ultraflex-9-ounce-standard-holed-mesh). The apertures of the fabric panels 30 may be configured to permit airflow into and/or out of the communications box 16, in exemplary embodiments. The panels 30 may provide over 400 combined square inches of airflow openings in exemplary embodiments, without limitation, though any size, shape, and/or type of panels 30 and associated airflow openings may be provided.

The communications box 16 may comprise, or be configured to receive, one or more electronic equipment items. Examples of such electronic equipment items include, by way of non-limiting example, wireless network connectivity devices 44 (e.g., antennae, routers, wi-fi devices, 5G equipment (e.g., small cell), signal repeaters, mesh modes, cellular network device, combinations thereof, or the like), air quality sensors 34, temperature sensors, position measurement devices (e.g., GPS, triangulation devices), humidity sensors, magnetometers, air pressure sensors, edge computers, processors, electronic storage devices, controllers, power modules, bulk energy storage devices, transformers, combinations thereof, or the like.

The communications box 16 may be generally cuboid in shape, though such is not required. The communications box 16 may be sized and/or shaped to accommodate certain wireless network connectivity devices 44 capable of signaling and/or rotating in 360 degrees azimuth, or substantially 360 degrees azimuth, by way of non-limiting example. For example, without limitation, interior space of the communications box 16 may be sized to permit 360 degrees rotational azimuth movement of at least certain of the wireless network connectivity devices 44, such as without contacting any interior surfaces of the communication box 16 and/or components therein. As another example, without limitation, the communications box 16 and/or interior space may be round, curved, oblong, circular, spherical, ovoid, cube, cuboid, combinations thereof, or the like, to accommodate such rotation.

To account for partial occlusion of panel 30 material over time, equipment within the communications box 16 may be selected which cumulatively requires approximately 50 square inches of airflow openings in exemplary embodiments, without limitation, though any requirement may be utilized. The equipment within the communications box 16 may be water and/or dust resistant, such as up to various ingress protection code (“IPC”) ratings (e.g., IP65, IP66, IP67).

The fabric panels 30 may provide shade and/or other solar protection to the electronics, such as, but not limited to the wireless network connectivity devices 44. The fabric panels 30 may, alternatively or additionally, act as a filter for ingested ambient air, such as by trapping debris. The fabric panels 30 may, alternatively or additionally, improve signal transmission and/or reception, such as compared to metal or glass panels. The fabric panels 30 may, alternatively or additionally, be printed or otherwise provided with advertisements, announcements, or other images, such as to increase available advertising space. Replacing the fabric panels 30 may be easier and less expensive that posters, boards, or the like.

One or more mounting devices 46, such as, but not limited to, rails, plates, surfaces, combinations thereof, or the like may be provided within the communications box 16, such as for receiving the electronic equipment. Portions of the mounting structure 12 may, alternatively or additionally, be configured to receive such electronic equipment.

One or more intake/exhaust areas 40 may be provided at the communications box 16. The one or more intake/exhaust areas 40 may comprise one or more apertures, grills, holes, filters, combinations thereof, or the like configured to facilitate the ingestion and/or exhaustion of ambient air, such as for thermally managing the communications box 16 or equipment thereof. The one or more intake/exhaust areas 40 may be located on, at, and/or along an upper edge of the communications box 16, though any number and/or location of intake/exhaust area(s) may be utilized. Multiple intake/exhaust areas 40 may be provided on, at, and/or along the upper edge of the communications box 16, by way of non-limiting example, and/or the intake/exhaust area(s) 40 may comprise multiple openings.

The intake/exhaust area 40 may comprise, or be located adjacent to, one or more fan assemblies 42. The one or more fan assemblies 42 may comprise any type or kind of fan, such as axial fan(s) and/or centrifugal fan(s). The fan(s) 42 may be operated to ingest ambient air into the communications box 16 and/or exhaust ambient air from the communications box 16. For example, without limitation, the fan(s) 42 may be configured and/or operated to ingest ambient air through the intake/exhaust area 40 where it is subsequently exhausted through the fabric panels 30. As another example, without limitation, the fan(s) 42 may be configured and/or operated to pull ambient air through the fabric panels 30 where it is subsequently exhausted through the intake/exhaust area 40. The fan(s) 42 may be configured for dedicated operation (e.g., ingestion or exhaustion) or may be reversable and/or reversibly operated such that ingestion and exhaustion may be reversed from time to time. The nature of the fabric panels 30 may permit the fan(s) 42 to operate less frequently and/or at lower speeds. In other exemplary embodiments, without limitation, the fan(s) 42 are not required and the communications box 16 may rely on passive airflow through the fabric panels 30.

The communications box 16 may be fluidly separated from the subassemblies 14, the one or more intake areas 15, and/or other areas of the assembly 10 in exemplary embodiments, without limitation. For example, without limitation, any ambient air ingested into the communications box 16 may have to first exit the communications box 16 and return to the ambient environment before being possibly re-ingested into the subassemblies 14, the one or more intake areas 15, and/or other areas of the assembly 10 (note: re-ingestion is not required). Movement back into the ambient environment may provide adequate mixing to reduce or avoid re-ingestion of pre-heated air.

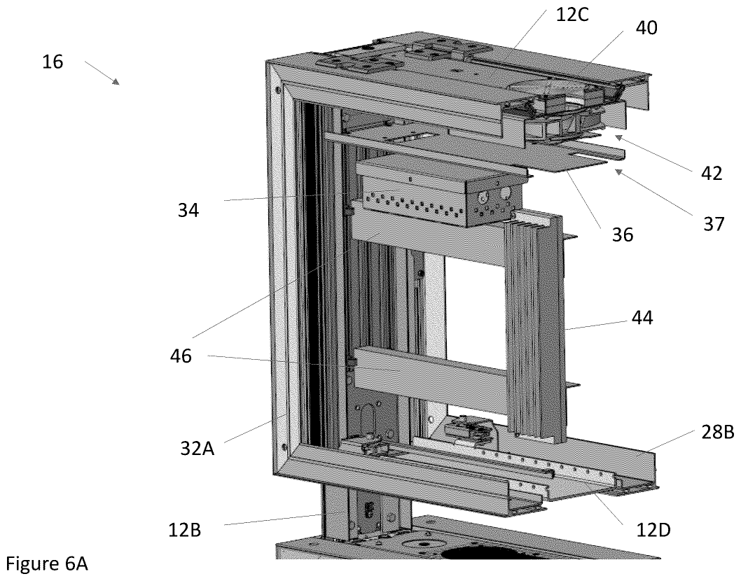

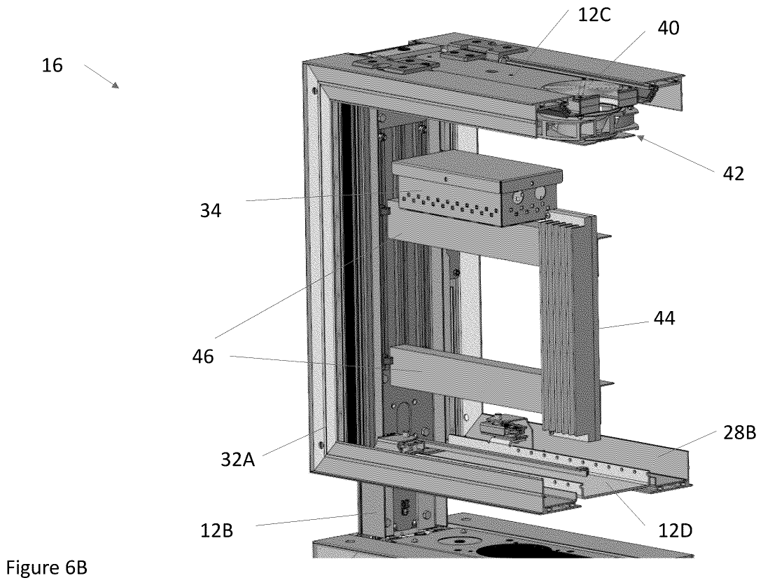

Referring particularly to FIG. 6A, the communication box 16 may comprise one or more convection aperture plates 36. The convection aperture plates 36 may comprise one or more apertures 37. The convection aperture plates 36 and/or other components of the communications box 16 may be as shown and/or described in the '227 Publication, the disclosures of which are hereby incorporated by reference as if fully restated herein. Referring particularly to FIG. 6B, the convection aperture plate(s) 36 are optional.

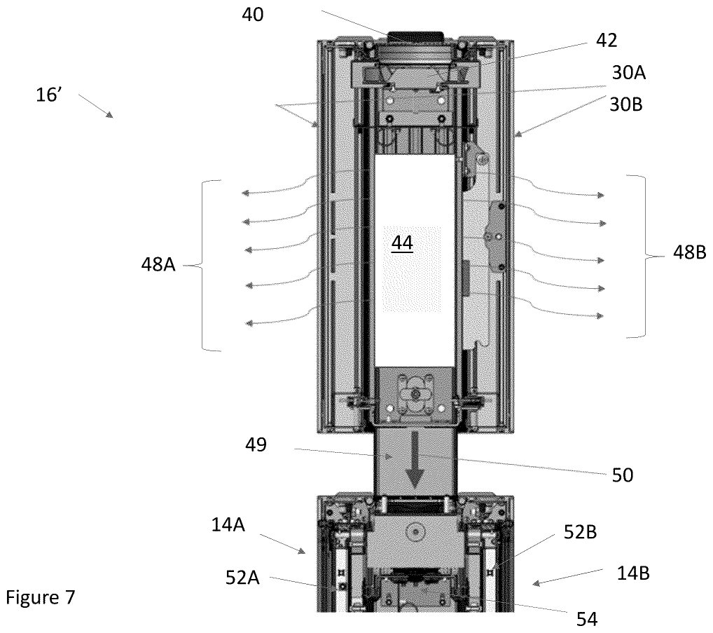

FIG. 7 illustrates another exemplary embodiment of the communications box 16′. Similar components may be numbered similarly with the addition of a prime (i.e., 16, 16′). The communications box 16′ may be fluidly connected to some or all of the subassemblies 14, such as by way of one or more channels 49 extending between the communications box 16 and the subassemblies 14 and/or a central channel 54 of the assembly 10 as generally indicated by flow 50. The central channel 54 may be fluidly separate from, or connected to, the subassemblies 14. The assembly 10 and/or airflow may be as shown and/or described in the '227 Publication, by way of non-limiting example. However, the fabric panels 30A, 30B may provide an additional exhaust area for ambient air ingested through the one or more intake/exhaust areas 40. This may reduce or eliminate pre-heating of the ambient air subsequently passed into the subassemblies 14 and/or other portions of the assembly 10.

Use of the fan(s) 42 is optional. For example, without limitation, thermal management for electronic components of the communications box 16′ may instead be accomplished through passive airflow into and/or out of the fabric panels 30. Furthermore, airflow may be reversed (e.g., on a dedicated and/or random or periodic basis) such that ambient air instead flows upward from the subassemblies 14 and/or central channel 54 into the communications box 16′.

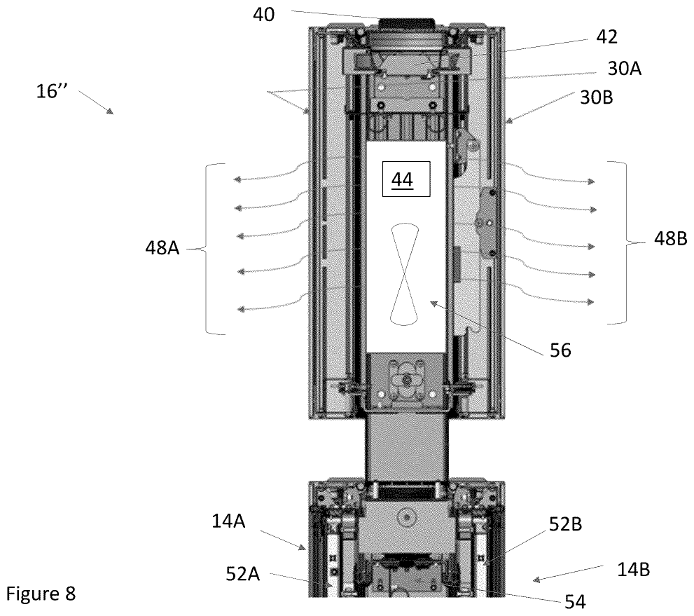

FIG. 8 illustrates another exemplary embodiment of the communications box 16″. Similar components may be numbered similarly with the addition of a single or double prime (i.e., 16, 16′, 16″). The communications box 16″ may be fluidly separated from the subassemblies 14. One or more fans 56 may be positioned within the communication box 16″ to force exhaustion of ingested ambient air through the fabric panels 30. The one or more fans 56 may alternatively, or additionally, be configured to force ingestion of ambient air through the fabric panels 30 and/or exhausted through the intake/exhaust area 40. The fan(s) 56 may be centrally located within the communications box 16, though any location may be utilized.

The fan(s) 42, which are optional, may be used to further ingest and/or exhaust the ambient air through the panels 30 and/or the intake/exhaust area 40.

The fan(s) 56 and/or 42 may be configured for a dedicated flow direction, may be reversible and/or configured for reversible operation, such as on a periodic or random basis, for sometimes ingesting and sometimes exhausting ambient air through the panels 30 and/or intake/exhaust area 40.

In other exemplary embodiments, without limitation, the fan(s) 42 and/or intake/exhaust area(s) 40 may not be required. In such embodiments, by way of non-limiting example, the fan(s) 56 may be configured to ingest ambient air through one of the fabric panels 30A and exhaust the ambient air through a same and/or another one of the fabric panels 30B. Any of the panels 30 may be used for ingestion and/or exhaustion. The fan(s) 56 may be periodically reversed to change the direction of flow. This may help to dislodge any debris embedded into the panels 30 and/or prolong panel 30 life.

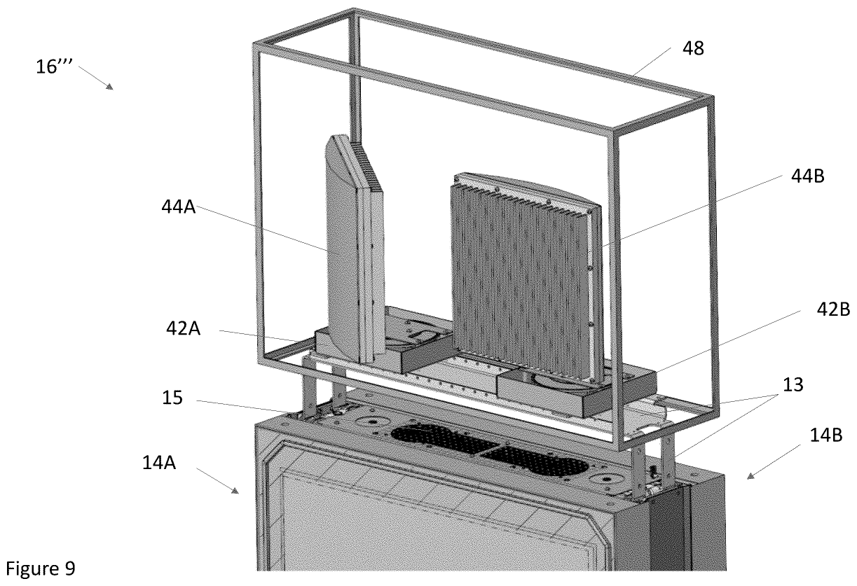

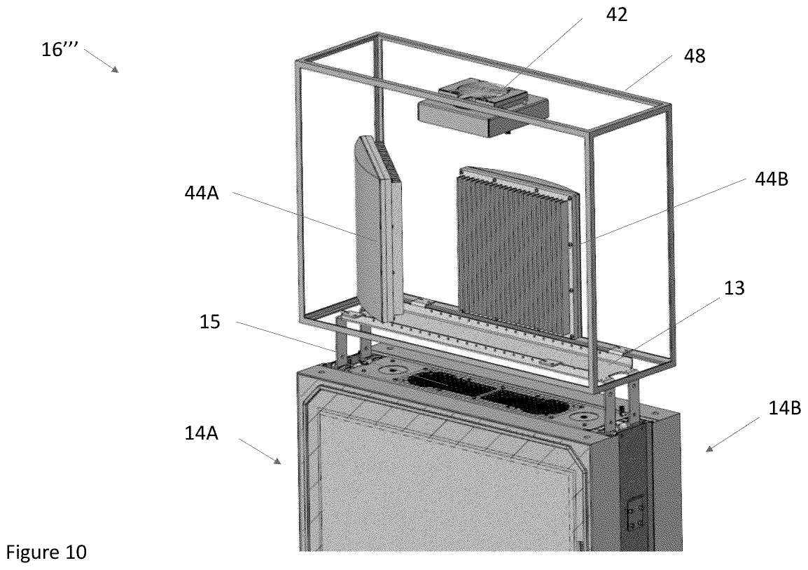

FIG. 9 and FIG. 10 illustrate another exemplary embodiment of the communications box 16″. Similar components may be numbered similarly with the addition of a single, double, or triple prime (i.e., 16, 16′, 16″, 16″). The communications box 16″ may be partially or wholly fluidly separate from, or connected to, the subassemblies 14. The communications box 16′″ may be elevated and spaced apart from the subassemblies 14.

A mounting platform 13 may extend from one or more of the subassemblies 14 and/or the mounting structure 12. The mounting platform 13 may elevate the communications box 16″ above and spaced apart from the intake(s) 15 to permit ingestion of ambient air. The mounting platform 13 may provide an elevated platform for one or more network connectivity devices 44A, 44B. In exemplary embodiments, without limitation, some or all of the network connectivity devices 44 may be configured for rotational movement, such as through a full 360 degrees of azimuth. Any number, type, and/or arrangement of network connectivity devices 44 may be utilized.

A framework subassembly 48 may be provided. The framework subassembly 48 may be connected to the mounting platform 13. Alternatively, or additionally, the framework subassembly 48 may be connected to the subassemblies 14 and/or the mounting structure 12. The framework subassembly 48 may comprise a number of members arranged into any of a number of shapes and/or sizes, such as, but not limited to, cube, cuboid, spherical, ovoid, combinations thereof, or the like. The members may comprise metallic and/or non-metallic material. The framework subassembly 48 may be configured to accommodate the one or more network connectivity devices 44, and optionally permit rotational movement of the same, such as through a full 360 degrees of azimuth.

The framework subassembly 48 may be configured to receive one or more of the fabric panels 30. The fabric panels 30 may be individually attached to the framework subassembly 48, such as one or more members thereof. The fabric panels 30 may be attached on a face-by-face basis, by way of non-limiting example. Such attachment may be accomplished by snap fitting, adhesive, fasteners (e.g., staples), sewing, combinations thereof, or the like. In exemplary embodiments, without limitation, the fabric panels 30 may comprise one or more pockets configured to accommodate some or all of the framework subassembly 48. For example, without limitation, the pockets may be slid over one or more members of the framework subassembly 48. The pockets may be sewn and/or may be selectively openable. For example, without limitation, the fabric panels 30 and/or the framework subassembly 48 may comprise, or be attached to, zippers, buttons, snaps, hook and loop fasteners, straps, buckles, combinations thereof, or the like for connecting the fabric panels 30 to the framework subassembly 48. Alternatively, or additionally, the fabric panels 30 may be provided or assembled into various shapes for fitting over one or more faces of the framework subassembly 48. For example, without limitation, the fabric panels 30 may comprise a partial cuboid shape configured to be stretched over, and snugly fit to, the framework subassembly 48. The fabric panels 30 may comprise stretchable material, one or more elastic bands, or be configured for closing about some or all of the framework subassembly 48, such as, but not limited to, by way of zippers, buttons, snaps, hook and loop fasteners, straps, buckles, combinations thereof, or the like. The fabric panels 30 may comprise, by way of non-limiting example, one or more attached protrusions configured to fit within one or more recesses of the framework subassembly 48, such as slots.

One or more fans 42 may be provided. As illustrated with particular regard to FIG. 9, multiple fans 42A, 42B may be positioned along the mounting platform 13. The mounting platform 13 may comprise one or more holes configured to permit airflow therethrough. As another example, without limitation, the fan(s) 42 may be attached to lower portions of the framework subassembly 48. As illustrated with particular regard to FIG. 10, the fan(s) 42 may be attached to upper portions of the framework subassembly 48. The fan(s) 42 may provide active cooling for the communications box 16″. The fan(s) 42 may be configured to ingest and/or exhaust ambient air into or from the communications box 16′″, such as through the fabric panels 30 in exemplary embodiments. Any number of fans 42 may be provided at any location(s) of the communications box 16″′.

In exemplary embodiments, without limitation, when attached, the fabric panels 30 may fully or partially enclose the communications box 16″′. For example, without limitation, air may be ingested and/or exhausted through the porous fabric material. As another example, without limitation, a bottom or other portion(s) of the fabric panels 30 may be partially or fully open to accommodate the mounting platform 13 and/or permit increased airflow. As another example, without limitation, a top portion may be partially or fully open to permit increased airflow.

Airflow through the communications box 16′″ may be partially or fully separate from airflow for the subassemblies 14 and/or may be connected. For example, without limitation, air ingested through the communications box 16′″ may be permitted or directed to the intake(s) 15. However, such is not required. Alternatively, or additionally, one or more diverters, barriers, baffles, or the like may be installed between the communications box 16″ and the intake(s) 15. The fabric panels 30 may be sized to extend to the subassemblies 14 and/or the mounting structure 12, such as to present a seamless appearance, though such is not required. In other exemplary embodiments, without limitation, a gap may be provided between the communications box 16″ and the subassemblies 14. The gap may be covered by one or more grills, filters, combinations thereof, or the like, though such is not required.

In other exemplary embodiments, without limitation, the fan(s) 42 and/or 56 may not be required in the communications box 16″, which may instead rely on passive airflow through the panel(s) 30.

Fluid separation shown and/or described herein may, for example, without limitation, be in accordance with various IPC ratings (e.g., IP65, IP66, IP67).

The assembly 10 may comprise additional electronic equipment, including but not necessarily limited to, electric vehicle (“EV”) charging equipment.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention.

Certain operations described herein may be performed by one or more electronic devices. Each electronic device may comprise one or more processors, electronic storage devices, executable software instructions, combinations thereof, and the like configured to perform the operations described herein. The electronic devices may be general purpose computers or specialized computing devices. The electronic devices may comprise personal computers, smartphone, tablets, databases, servers, or the like. The electronic connections and transmissions described herein may be accomplished by wired or wireless means. The computerized hardware, software, components, systems, steps, methods, and/or processes described herein may serve to improve the speed of the computerized hardware, software, systems, steps, methods, and/or processes described herein.

What is claimed is:

1. A display assembly comprising:
a mounting structure;
an electronic display subassembly attached to the mounting structure; and
a communications box attached to the mounting structure and having an interior space for electronic equipment which is located above, and spaced apart from, the electronic display subassembly, said communications box comprises a fabric panel, which is gas permeable and occupies at least a majority of a side of the communications box.

2. The display assembly of claim 1 wherein:
the side is a front side of the communications box.

3. The display assembly of claim 2 further comprising:
a frame defining, at least in part, the front side of the communications box, wherein the fabric panel is secured within the frame.

4. The display assembly of claim 3 further comprising:
a second frame defining, at least in part, a rear side of the communications box; and
a second fabric panel secured within the second frame, wherein the second fabric panel occupies at least a majority of the rear side of the communications box.

5. The display assembly of claim 1 further comprising:
an aperture located at an upper surface and/or a lower surface of the communications box; and
a fan located within the interior space of the communications box, which when activated, ingests ambient air through the aperture and exhausts the ambient air through the fabric.

6. The display assembly of claim 1 further comprising:
an aperture located at an upper surface and/or a lower surface of the communications box; and
a fan at the communications box, which when activated, ingests ambient air through the fabric and exhausts the ambient air through the aperture.

7. The display assembly of claim 6 further comprising:
an open airflow pathway extending within the electronic display subassembly, wherein the aperture is provided at the lower surface of the communications box and provides a fluid connection between the interior space and the open airflow pathway, such that, when the fan is activated, the ambient air ingested through the fabric and the aperture travels towards the open loop pathway.

8. The display assembly of claim 7 further comprising:
a second aperture located at the upper surface of the communications box such that, when the fan is activated, the ambient air is also ingested through the second aperture to generate a combined flow towards the open loop pathway.

9. The display assembly of claim 1 further comprising:
an open airflow pathway extending within the electronic display subassembly;
a mounting platform structure which extends between a lower surface of the interior space of the communications box and an upper surface of the mounting structure; and
an intake area for the open airflow pathway located below a lower surface of the communications box and an upper surface of the mounting platform structure, and above an upper surface of the electronic display subassembly.

10. The display assembly of claim 9 wherein:
the communications box comprises a framework subassembly mounted to the mounting platform structure.

11. The display assembly of claim 1 wherein:
the framework subassembly comprises members forming a generally cuboid shape; and
the interior space of the communications box is generally cuboid shaped.

12. The display assembly of claim 1 further comprising:
the electronic equipment, wherein said electronic equipment comprises wireless electronic communications equipment.

13. The display assembly of claim 12 further comprising:
an air quality sensor located within the communications box.

14. The display assembly of claim 1 wherein:
the electronic display subassembly comprises a cover layer, a layer of liquid crystals, and light emitting diodes.

15. The display assembly of claim 1 wherein:
the mounting structure is configured for mounting to a ground surface.

16. A communications box for a display assembly having a mounting structure and an
electronic display assembly attached to said mounting structure, said
communications box comprising:
panels and/or members defining, at least in part, an interior space for electronic equipment; and
a gas permeable fabric panel forming part of, or secured at least in part by, the panels and/or members of a side of the communications box, wherein the gas permeable fabric panel occupies at least a majority of the surface area of the side of the communications box.

17. The communications box of claim 16 wherein:
said communications box is configured to be connected to the mounting structure such that said interior space is located above, and spaced apart from, the electronic display subassembly.

18. The communications box of claim 16 further comprising:
electronic equipment located at the interior space; and
a fan located within the communications box for moving ambient air through the fabric panel when activated.

19. A method of thermally managing wireless electronic communications equipment
of a display assembly, said method comprising:
activating a fan located within an interior space of a communications box attached to a mounting structure of the display assembly such that ambient air is moved through a fabric panel of the communications box occupying at least a majority of a surface area of a side of the communications box to remove heat generated by the wireless electronic communications equipment located within the interior space.
